(19) United States
(12) Patent Application Publication
(10) Pub. No.: US 2022/0208587 A1
(43) Pub. Date: Jun. 30, 2022

(54) SUBSTRATE COOLING UNIT, SUBSTRATE PROCESSING APPARATUS, SUBSTRATE PROCESSING METHOD, METHOD FOR MANUFACTURING SEMICONDUCTOR DEVICE, AND NON-TRANSITORY COMPUTER-READABLE RECORDING MEDIUM

(71) Applicant: KOKUSAI ELECTRIC CORPORATION, Tokyo (JP)

(72) Inventors: Takuya SAITO, Toyama-shi (JP); Askira TAKAHASHI, Toyama-shi (JP); Shin HIYAMA, Toyama-shi (JP)

(73) Assignee: KOKUSAI ELECTRIC CORPORATION, Tokyo (JP)

(21) Appl. No.: 17/692,688

(22) Filed: Mar. 11, 2022

Related U.S. Application Data
(63) Continuation of application No. PCT/JP2020/033693, filed on Sep. 4, 2020.

(30) Foreign Application Priority Data
Sep. 17, 2019 (JP) 2019-167921

(51) Int. Cl. H01L 21/68; H01L 21/687; H01L 21/67; H01L 21/66

(52) U.S. Cl. CPC H01L 21/681; H01L 22/10; H01L 21/67109; H01L 21/68764

(57) ABSTRACT

A substrate cooling unit includes a substrate holding mechanism holding a substrate horizontally, a driver that raises and lowers the substrate holding mechanism, a cooling plate having a surface facing a surface of the substrate, a laser emitter disposed at one lateral end of a space in which the substrate is raised and lowered and that emits a laser beam distributed with a width in a direction in which the substrate holding mechanism is raised and lowered and parallel to the surface of the substrate. A laser receiver disposed at the other lateral end of the space and that acquires light receiving position specifying information indicating a position at which the laser beam is received in the direction in which the substrate holding mechanism is raised and lowered. A calculator that calculates a distance between the cooling plate and the substrate based on the light receiving position specifying information.

### CROSS-REFERENCE TO RELATED PATENT APPLICATION

This application is a bypass continuation application of PCT International Application No. PCT/JP2020/033693, filed on Sep. 4, 2020, in the WIPO, the international application being based upon and claiming the benefit of priority from Japanese Patent Application No. 2019-167921, filed on Sep. 17, 2019, in the Japanese Patent Office, the entire contents of which are hereby incorporated by reference.

### BACKGROUND

### 1. Field

The present disclosure relates to a substrate cooling unit, a substrate processing apparatus, a substrate processing method, a method for manufacturing a semiconductor device, and a non- transitory computer-readable recording medium.

### 2. Related Art

As a step of a process of manufacturing a semiconductor device, a substrate may be heated in a film formation step, an annealing step, or the like, and be then transferred to a cooler to be cooled (for example, Japanese Patent Application Laid-open No. 2003-100579).

### SUMMARY

In substrate cooling, it is desirable to cool the substrate with desired cooling characteristics. The cooling characteristics of the substrate vary depending on a substrate position during cooling, such as a distance between a cooling member and the substrate. Therefore, during cooling, it is needed to perform cooling so as to approach desired cooling characteristics by disposing the substrate at an accurate position with good reproducibility.

According to one or more embodiments of the present disclosure, there is provided a technology including: a substrate holding mechanism that holds a substrate horizontally, a driver that raises and lowers the substrate holding mechanism, a cooling plate having a surface facing a surface of the substrate held by the substrate holding mechanism; a laser emitter that is disposed at one lateral end of a space in which the substrate held by the substrate holding mechanism is raised and lowered and that emits a laser beam distributed with a width in a direction in which the substrate holding mechanism is raised and lowered and parallel to the surface of the substrate held by the substrate holding mechanism, a laser receiver that is disposed at the other lateral end of the space and that acquires light receiving position specifying information indicating a position at which the laser beam emitted from the laser emitter is received in the direction in which the substrate holding mechanism is raised and lowered, and a calculator that calculates a distance between the facing surface of the cooling plate and the facing surface of the substrate held by the substrate holding mechanism to the cooling plate based on the light receiving position specifying information acquired by the laser receiver.

### DETAILED DESCRIPTION

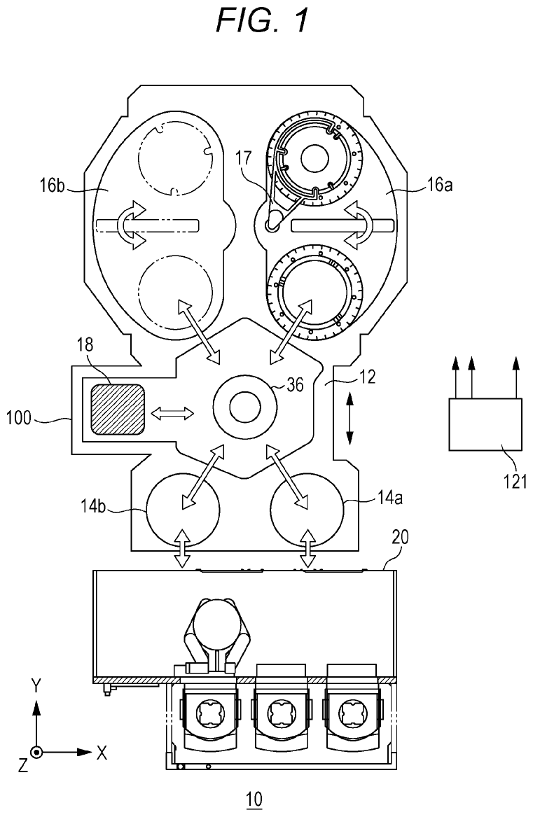

FIG. 1 is a schematic configuration diagram of a substrate processing apparatus used in one or more embodiments of the present disclosure, and is a diagram illustrating a horizontal cross section thereof viewed from a top surface.

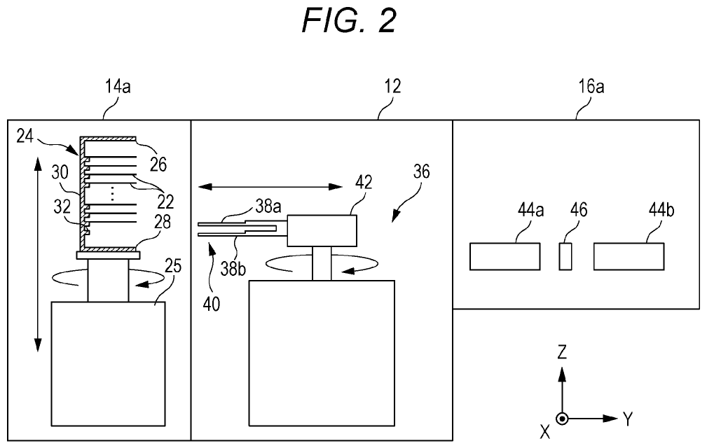

FIG. 2 is a schematic configuration diagram of a substrate processing apparatus used in one or more embodiments of the present disclosure, and is a diagram illustrating a vertical cross section thereof viewed from a side surface.

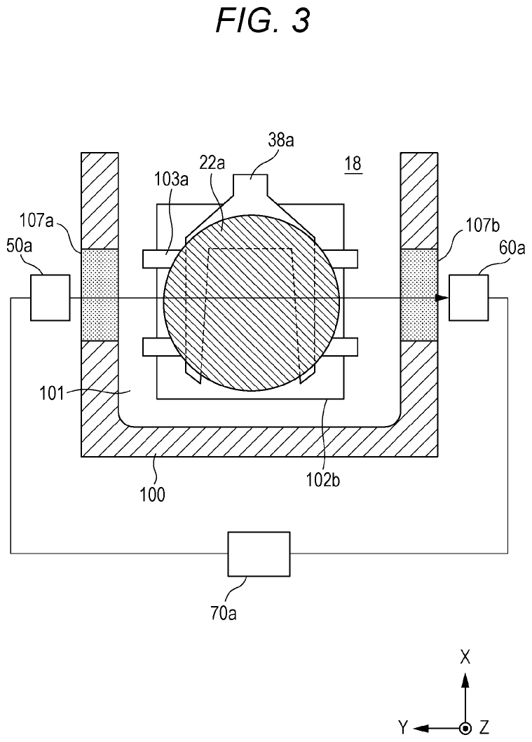

FIG. 3 is a schematic configuration diagram of a substrate cooling unit used in one or more embodiments of the present disclosure, and is a diagram illustrating a horizontal cross section thereof viewed from a top surface.

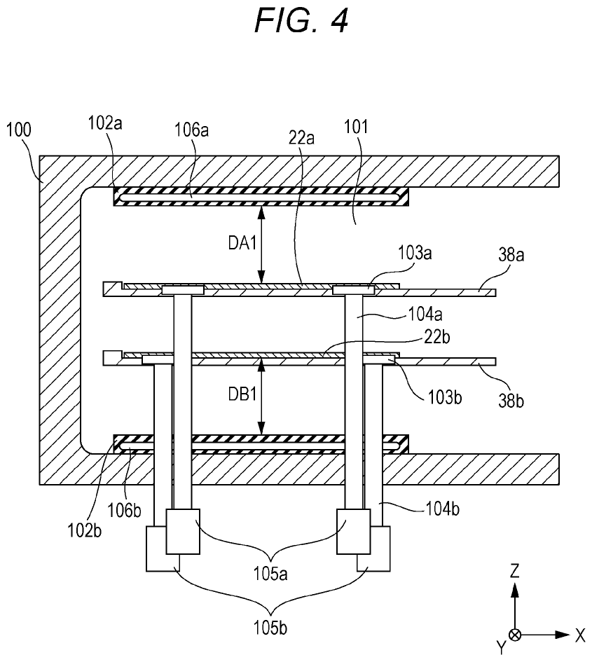

FIG. 4 is a schematic configuration diagram of a substrate cooling unit used in one or more embodiments of the present disclosure, and is a diagram illustrating a vertical cross section thereof viewed from a side surface in a state where a substrate is at a substrate loading/unloading position.

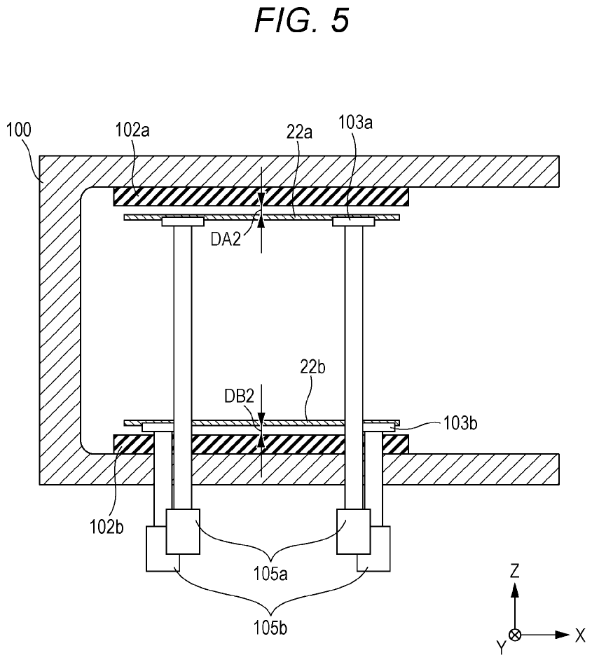

FIG. 5 is a schematic configuration diagram of a substrate cooling unit used in one or more embodiments of the present disclosure, and is a diagram illustrating a vertical cross section thereof viewed from a side surface in a state where a substrate is at a substrate cooling position.

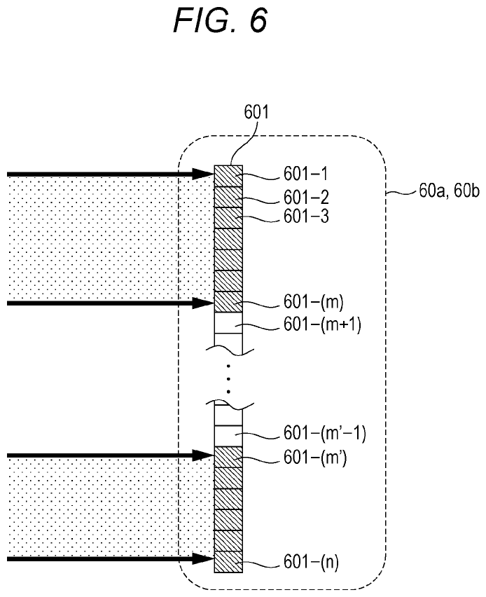

FIG. 6 is an explanatory diagram illustrating an array of light receiving elements constituting a laser sensor unit used in an example of the present disclosure.

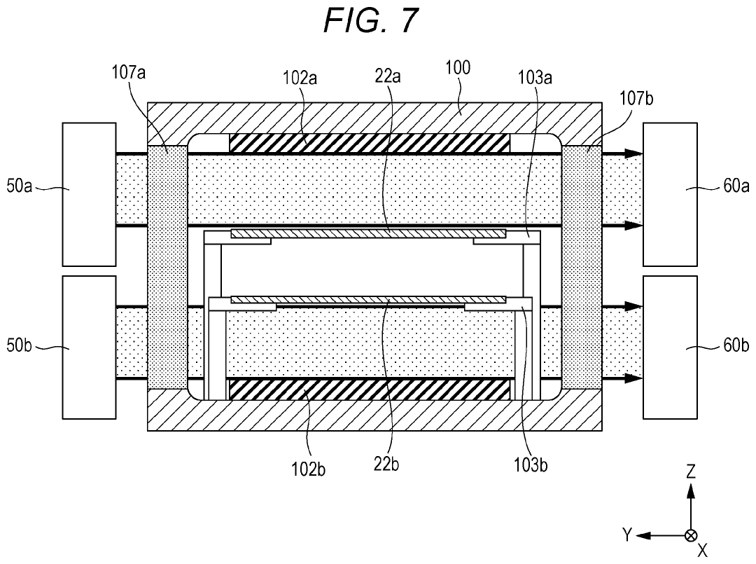

FIG. 7 is a schematic configuration diagram of a substrate cooling unit used in an example of the present disclosure, and is an explanatory diagram illustrating aspects of laser emission and light reception at a substrate loading/unloading position.

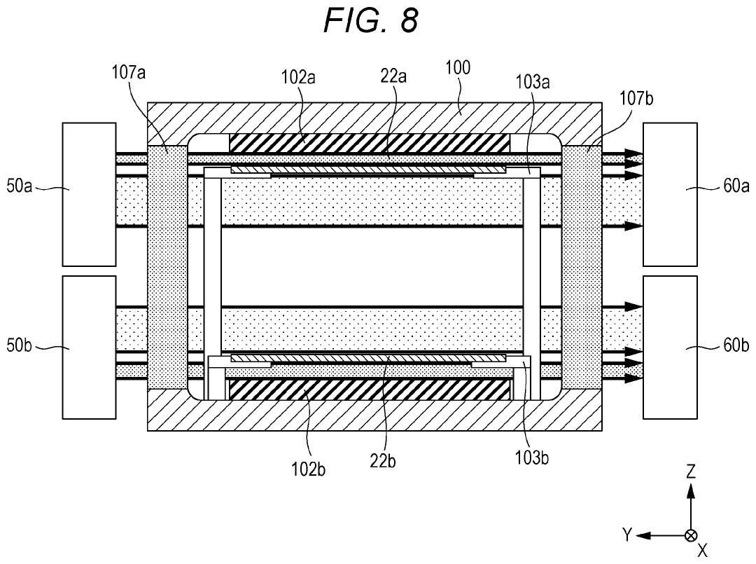

FIG. 8 is a schematic configuration diagram of a substrate cooling unit used in an example of the present disclosure, and is an explanatory diagram illustrating aspects of laser emission and light reception at a substrate cooling position.

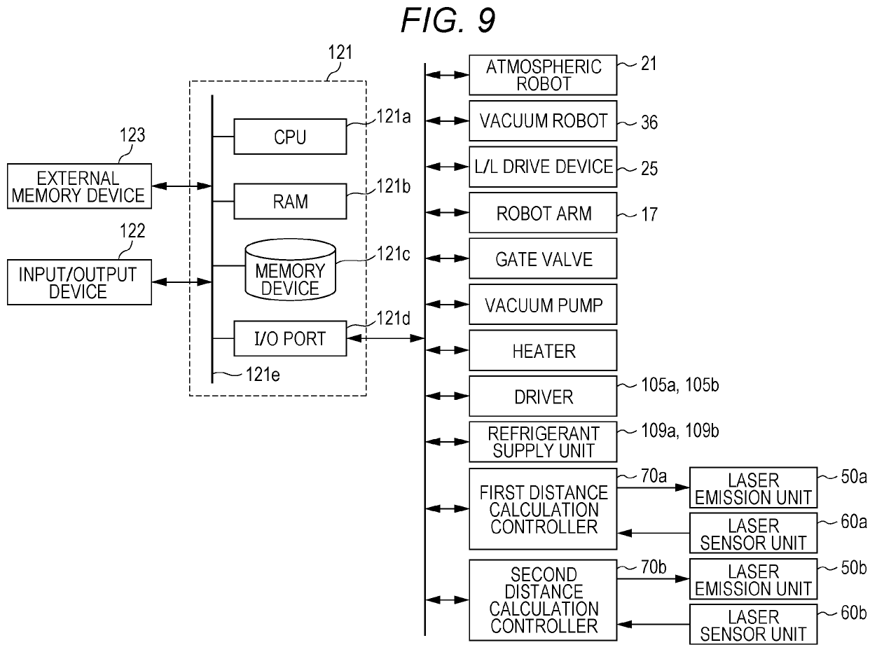

FIG. 9 is a diagram illustrating a configuration of a controller of a substrate processing apparatus suitably used in an embodiment of the present disclosure.

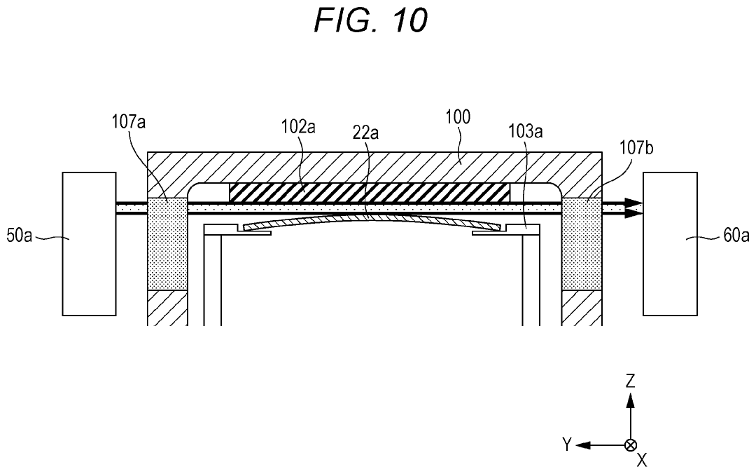

FIG. 10 is a schematic configuration diagram of a substrate cooling unit used in an example of the present disclosure, and is an explanatory diagram illustrating aspects of laser emission and light reception in a case where warpage is generated in a substrate.

### EMBODIMENTS

Hereinafter, one or more embodiments (also simply referred to as “embodiments”) according to the technique of the present disclosure will be described with reference to FIGS. 1 through 10.

(1) Substrate Processing Apparatus

A configuration of a substrate processing apparatus 10 according to the present embodiment will be described below with reference to FIGS. 1 and 2.

The substrate processing apparatus 10 includes load lock chambers 14a and 14b and two processing chambers 16a and 16b around a transfer chamber 12. The transfer chamber 12 includes a cooling chamber 101 formed inside a cooling casing 100, and a substrate cooling unit 18 is disposed inside the cooling chamber 101. An atmospheric transfer chamber 20 is disposed on the opposite side of the load lock chambers 14a and 14b with respect to the transfer chamber 12. The atmospheric transfer chamber 20 includes a mounting stage on which a plurality of pods capable of housing up to twenty five substrates 22 (wafers in the present embodiment) at regular intervals in a longitudinal direction can be mounted. In addition, the atmospheric transfer chamber 20 includes an atmospheric robot 21 that transfers the substrate between the atmospheric transfer chamber 20 and the load lock chambers 14a and 14b.

Between the transfer chamber 12 and the load lock chambers 14a and 14b, between the transfer chamber 12 and the processing chambers 16a and 16b, and between the load lock chambers 14a and 14b and the atmospheric transfer chamber 20, gate valves that block atmospheres of the two spaces are disposed, respectively. Vacuum pumps are connected to the transfer chamber 12, the load lock chambers 14a and 14b, and the processing chambers 16a and 16b, respectively, and each of the spaces is controlled so as to have a desired pressure. The substrate processing apparatus 10 includes a controller 121. The controller 121 controls the entire apparatus in the above configuration.

(Vacuum Robot)

The transfer chamber 12 includes a vacuum robot 36 as a substrate transfer device configured to be able to transfer the substrate 22 to and from the load lock chambers 14a and 14b, the processing chambers 16a and 16b, and the substrate cooling unit 18. The vacuum robot 36 includes an arm 42 with a pair of fingers 40, and the pair of fingers 40 includes an upper finger 38a (first substrate transfer support) and a lower finger 38b (second substrate transfer support) as substrate transfer supports.

The upper finger 38a and the lower finger 38b both have the same bifurcated shape. In addition, the upper finger 38a and the lower finger 38b are disposed so as to overlap each other at a predetermined interval in an up-down direction (vertical direction), and are configured to extend substantially horizontally in the same direction from the arm 42 to support the substrate 22.

The arm 42 is configured to rotate about a rotation axis that rises and descends in the vertical direction, to move in the horizontal direction, and to be able to simultaneously transfer the two substrates 22 in the up-down direction and the horizontal direction. Hereinafter, the substrate 22 supported and transferred by the upper finger 38a is particularly referred to as a substrate 22a, and the substrate 22 supported and transferred by the lower finger 38b is particularly referred to as a substrate 22b.

(Load Lock Chamber)

Each of the load lock chambers 14a and 14b includes a substrate support body 24 that houses, for example, the twenty five substrates 22 at regular intervals in a longitudinal direction. The substrate support body 24 includes an upper plate 26, a lower plate 28, and a support column 30 connecting the upper plate 26 and the lower plate 28 to each other. Mounters 32 are formed in parallel with each other on a longitudinal inner side of the support column 30. The substrate support body 24 is configured to be moved in the up-down direction and rotated by a load lock (“L/L”) drive device 25 in each of the load lock chambers 14a and 14b.

When the substrate 22 is loaded from the transfer chamber 12 into the load lock chamber 14a or 14b, the substrate 22 is transferred to the mounter 32 by the following operation. That is, the pair of fingers 40 supporting the substrate 22 is inserted between the mounters 32 in the load lock chamber 14a or 14b. Next, the substrate support body 24 moves in the vertical direction. By performing such an operation, the two substrates mounted on the pair of fingers 40 can be transferred to upper surfaces of the mounters 32. In addition, by performing an operation opposite to the operation when the wafer is loaded from the transfer chamber 12 into the load lock chamber 14a, the wafer mounted on the mounter 32 is unloaded to the transfer chamber 12.

(Processing Chamber)

Each of the processing chambers 16a and 16b has a reaction chamber, which includes substrate holding tables 44a and 44b and a robot arm 17. A partition member 46 is disposed in a space between the substrate holding tables 44a and 44b. The robot arm 17 is configured to receive the substrate 22 held by the vacuum robot 36 and to mount the substrate 22 on each of the substrate holding tables 44a and 44b. In the processing chambers 16a and 16b, the two substrates 22 mounted on the substrate holding tables 44a and 44b, respectively, are simultaneously processed in the same space. A heater is built in each of the substrate holding tables 44a and 44b, and can raise the temperature of the substrate 22 to, for example, 400° C. or higher.

(Substrate Cooling Unit)

The substrate cooling unit 18 will be described with reference to FIGS. 3 to 5. The substrate cooling unit 18 is disposed in the cooling chamber 101 formed by the cooling casing 100. The substrate cooling unit 18 includes cooling plates 102a (first substrate cooling plate) and 102b (second substrate cooling plate) as a plurality of substrate cooling members, substrate holders 103a (first substrate holder) and 103b (second substrate holder), and support shafts 104a and 104b, which will be described later. The substrate cooling unit 18 may be regarded as including drivers 105a and 105b, and furthermore, may be regarded as including refrigerant supply units (refrigerant suppliers) 109a and 109b that supply a refrigerant to refrigerant flow paths 106a and 106b disposed in the cooling plates 102a and 102b, respectively.

The substrate cooling unit 18 includes two sets of substrate holding mechanisms for holding the substrates 22a and 22b, respectively. The substrate holding mechanism that holds the substrate 22a includes four substrate holders 103a configured to hold the substrate 22a on an upper surface, and four support shafts 104a connected to and supporting the substrate holders 103a, respectively. Similarly, the substrate holding mechanism that holds the substrate 22b includes four substrate holders 103b configured to hold the substrate 22b on an upper surface, and four support shafts 104b connected to and supporting the substrate holders 103b, respectively. Note that, in the present embodiment, the substrate holders 103a and 103b are made of plate-like members, but the present disclosure is not limited thereto, and any structure may be used as long as the substrate 22 can be supported at a point or a plane, for example, the substrate holders 103a and 103b may be formed into a pin shape that supports the substrate 22 at a point from a lower surface.

The substrate holding mechanisms are configured to be raised and lowered by the drivers (drive devices) 105a and 105b connected to the support shafts 104a and 104b, respectively. Each of the drivers 105a and 105b is configured by, for example, an air cylinder. The drivers 105a and 105b are controlled, and the substrates 22a and 22b held by the substrate holders 103a and 103b can be thereby raised and lowered between a substrate loading/unloading position and a substrate cooling position described later, respectively.

The cooling plates 102a and 102b are made of metal such as stainless steel, for example. The refrigerant flow paths 106a and 106b through which a refrigerant flows are disposed inside the cooling plates 102a and 102b, respectively, and the refrigerant flow paths 106a and 106b are configured to cool a lower surface side of the cooling plate 102a and an upper surface side of the cooling plate 102b, respectively. As a result, the substrates 22 supported near the cooling plates 102a and 102b by the substrate holders 103a and 103b are cooled, respectively. The substrate cooling unit 18 further includes the refrigerant supply units (refrigerant suppliers) 109a and 109b that supply a refrigerant to the refrigerant flow paths 106a and 106b, respectively.

On side surfaces of the cooling casing 100, light transmission windows 107a and 107b that transmit light such as a laser beam between the outside and the inside of the cooling chamber 101 are disposed at positions facing each other with the cooling chamber 101 interposed therebetween.

(Laser Emission Unit)

Outside the cooling casing 100, laser emission units (laser emitters) 50a and 50b as laser emitters configured to emit a laser beam into the cooling chamber 101 through the light transmission window 107a are disposed at positions facing the light transmission window 107a. The laser emission units 50a and 50b emit a laser beam in a direction parallel to surfaces of the substrates 22 held on the substrate holders 103a and 103b, respectively, preferably in a direction passing through a central axis of the surfaces of the substrates 22.

In addition, each of the laser emission units 50a and 50b is configured to emit a laser beam distributed with a width in the vertical direction (that is, a direction in which the substrate holding mechanism is raised and lowered). Specifically, a laser beam emitted from a laser oscillator such as a laser diode is diffused in the vertical direction by a diffusion lens or the like, whereby a laser beam distributed with a width in the vertical direction can be configured. In addition, a plurality of laser oscillators such as laser diodes arrayed at predetermined intervals in the vertical direction may be included, and a plurality of laser beams emitted from the laser oscillators may constitute the laser beam distributed with a width in the vertical direction.

(Laser Sensor Unit)

Outside the cooling casing 100, laser sensor units (laser sensors) 60a and 60b as laser receivers configured to receive laser beams emitted from the laser emission units 50a and 50b through the light transmission window 107b are disposed at positions facing the light transmission window 107b. The laser emission unit 50a and the laser sensor unit 60a are disposed so as to face each other with the cooling chamber 101 interposed therebetween. Similarly, the laser emission unit 50b and the laser sensor unit 60b are disposed so as to face each other with the cooling chamber 101 interposed therebetween.

The laser sensor units 60a and 60b are configured to receive laser beams emitted from the laser emission units 50a and 50b and distributed with a width in the vertical direction, respectively, and to acquire, in the vertical direction (that is, the direction in which the substrate holding mechanism is raised and lowered), at least one of information of the position (light receiving position) of a light receiving element that has received a laser beam and information of the position (non-light receiving position) of a light receiving element that has not received a laser beam. Hereinafter, information specifying the light receiving position including the light receiving position and the non-light receiving position may be collectively referred to as light receiving position specifying information.

Specifically, as illustrated in FIG. 6, by including an array 601 of a plurality of light receiving elements such as charge coupled devices (CCDs) that detect light and are arrayed at predetermined intervals in the vertical direction, each of the laser sensor units 60a and 60b can be configured to receive and detect a laser beam distributed with a width in the vertical direction. In the present embodiment, the array 601 includes n light receiving elements including light receiving elements 601-1 to 601-n (n is a natural number). For example, as illustrated in FIG. 6, in a case where a laser beam having a width of the light receiving elements 601-1 to 601-m (m is a natural number) is received, the laser sensor units 60a and 60b each detect that the light receiving elements 601-1 to 601-m have received light, and acquire a position where the light receiving elements 601-1 to 601-m are arrayed as a light receiving position. On the other hand, the laser sensor units 60a and 60b each acquire a position where the light receiving elements 601-(m+1) to 601-n that have not received a laser beam are arrayed as a non-light receiving position.

The array 601 is disposed at a position which has a width (length) that covers at least the entire distribution width of laser beams emitted from the laser emission units 50a and 50b in the vertical direction and at which light can be received in the entire distribution width. In addition, an array interval between the light receiving elements in the array 601 can be appropriately determined according to accuracy of laser detection, and the interval can be selected, for example, in a range of 1 μm to 1 mm, preferably in a range of 5 to 10 μm.

As illustrated in FIG. 7, in the present embodiment, the laser emission unit 50a emits a laser beam having a distribution from a height position of a lower surface of the cooling plate 102a (that is, a surface facing the substrate 22a) to a height position of an upper surface of the substrate 22a at a substrate loading/unloading position described later. That is, the distribution of the laser beam includes the height position of a lower surface of the cooling plate 102a as an upper end and includes a range in a height direction in which the substrate 22a is raised and lowered. Similarly, the laser emission unit 50b emits a laser beam having a distribution from a height position of an upper surface of the cooling plate 102b (that is, a surface facing the substrate 22b) to a height position of a lower surface of the substrate 22b at a substrate loading/unloading position described later.

In other words, each of the laser emission units 50a and 50b is disposed at one lateral end of a space in which the substrate 22 held by the substrate holding mechanism is raised and lowered (a space in which the substrate 22 is raised and lowered between a substrate loading/unloading position and a substrate cooling position described later), and is configured to emit a laser beam distributed with the width of the space in the vertical direction (height direction) toward the space.

In addition, as illustrated in FIG. 7, the laser sensor unit 60a is configured to be able to receive a laser beam having a distribution from a height position of a lower surface of the cooling plate 102a to a height position of an upper surface of the substrate 22a at a substrate loading/unloading position described later in the entire distribution range of the laser beam. That is, in the array 601 of the laser sensor units 60a, the light receiving elements are arrayed so as to be able to receive a laser beam at least in such a distribution range in the vertical direction. In the present embodiment, in particular, the laser sensor unit 60a is disposed such that the uppermost light receiving element 601-1 of the array 601 is disposed at the height position of the lower surface of the cooling plate 102a.

Similarly, the laser sensor unit 60b is configured to be able to receive a laser beam having a distribution from a height position of an upper surface of the cooling plate 102b to a height position of a lower surface of the substrate 22b at a substrate loading/unloading position described later in the entire distribution range of the laser beam. That is, in the array 601 of the laser sensor unit 60b, the light receiving elements are arrayed so as to be able to receive a laser beam at least in such a distribution range in the vertical direction. In the present embodiment, in particular, the laser sensor unit 60b is disposed such that the lowermost light receiving element 601-n of the array 601 is disposed at the height position of the upper surface of the cooling plate 102b.

Therefore, each of the laser sensor units 60a and 60b is disposed at the other lateral end of a space in which the substrate 22 held by the substrate holding mechanism is raised and lowered, and is configured to receive a laser beam emitted toward the space and distributed with the width of the space in the vertical direction.

Here, the substrate loading/unloading position and the substrate cooling position will be described with reference to FIGS. 3 to 5. FIGS. 3 and 4 illustrate a state when the substrate 22 is transferred (loaded) into the substrate cooling unit 18 and a state when the substrate 22 is unloaded from the substrate cooling unit 18. The position of the substrate 22 in this state is referred to as the substrate loading/unloading position.

In a step of transferring the substrate 22 to the substrate cooling unit 18, as illustrated in FIG. 4, the substrates 22a and 22b loaded into the cooling chamber 101 in a state of being supported on the fingers 38a and 38b are lowered by the vacuum robot 36, respectively. As a result, the substrates 22a and 22b are mounted on upper surfaces of the substrate holders 103a and 103b that are raised or lowered to the positions at the time of loading and unloading the substrates, respectively.

In addition, in a step of unloading the substrate 22 from the substrate cooling unit 18, the substrate holders 103a and 103b are raised or lowered to the positions at the time of loading and unloading the substrates in a state where the substrates 22a and 22b are held, respectively. Thereafter, the vacuum robot 36 raises the fingers 38a and 38b inserted below the substrates 22a and 22b, respectively, and the substrates 22a and 22b are thereby supported on the fingers 38a and 38b, respectively. Thereafter, the substrates 22a and 22b supported on the fingers 38a and 38b are unloaded from the substrate cooling unit 18, respectively.

In addition, FIG. 5 illustrates a state when the substrate 22 is cooled by being brought close to the cooling plate 102a or 102b. The position of the substrate 22 in this state is referred to as the substrate cooling position.

In the step of cooling the substrate 22, as illustrated in FIG. 5, the substrate holder 103a is raised by the driver 105a, and the substrate 22a held on the substrate holder 103a is transferred to a position to be cooled by the cooling plate 102a. Similarly, the substrate holder 103b is lowered by the driver 105b, and the substrate 22b held on the substrate holder 103b is transferred to a position to be cooled by the cooling plate 102b.

(Distance Calculation Controller)

The laser emission unit 50a and the laser sensor unit 60a are connected to a first distance calculation controller 70a as a first calculator. Similarly, the laser emission unit 50b and the laser sensor unit 60b are connected to a second distance calculation controller 70b as a second calculator. In addition, the first distance calculation controller 70a and the second distance calculation controller 70b are connected to the controller 121. The first distance calculation controller 70a and the second distance calculation controller 70b acquire data (information) of at least one of the light receiving position and the non-light receiving position from the laser sensor units 60a and 60b, respectively.

The first distance calculation controller 70a calculates a distance (substrate distance DA) from the height position of a lower surface of the cooling plate 102a to the height position of an upper surface of the substrate 22a held by the substrate holder 103a based on the acquired data.

Specifically, the first distance calculation controller 70a acquires data of the light receiving position from the laser sensor unit 60a, and calculates the width (length) of the light receiving position continuous from the light receiving element 601-1 as the substrate distance DA. That is, the first distance calculation controller 70a calculates, as the substrate distance DA, the width (length) of the light receiving position continuous from the position of the light receiving element 601-1 disposed at the height position of the lower surface of the cooling plate 102a as a reference point.

Note that, as an example of another calculation method, the first distance calculation controller 70a may acquire data of the non-light receiving position from the laser sensor unit 60a, and calculate, as the substrate distance DA, a length to a non-light receiving position that first appears on the array 601 when viewed from the position of the light receiving element 601-1.

Similarly, the second distance calculation controller 70b calculates a distance (substrate distance DB) from the height position of an upper surface of the cooling plate 102b to the height position of a lower surface of the substrate 22b held by the substrate holder 103b based on the acquired data.

Specifically, the second distance calculation controller 70b acquires data of the light receiving position from the laser sensor unit 60b, and calculates the width (length) of the light receiving position continuous from the light receiving element 601-n as the substrate distance DB. That is, the second distance calculation controller 70b calculates, as the substrate distance DB, the width (length) of the light receiving position continuous from the position of the light receiving element 601-n disposed at the height position of the upper surface of the cooling plate 102b as a reference point.

Note that, as an example of another calculation method, the second distance calculation controller 70b may acquire data of the non-light receiving position from the laser sensor unit 60b, and calculate, as the substrate distance DB, a length to a non-light receiving position that first appears on the array 601 when viewed from the position of the light receiving element 601-n.

(Case of Substrate Loading/Unloading Position)

In a case where the substrate 22 is at the substrate loading/unloading position, as illustrated in FIG. 7, the laser beams emitted from the laser emission units 50a and 50b are received by the light receiving elements 601-1 to 601-n (that is, all the light receiving elements) of the array 601 of the laser sensor units 60a and 60b, respectively. Therefore, the width (length) of the array of the light receiving elements 601-1 to 601-n, which is the width (length) of the light receiving position continuous from the light receiving element 601-1 of the array 601 of the laser sensor unit 60a, is calculated as the substrate distance DA (that is, a substrate distance DA1). Similarly, the width (length) of the array of the light receiving elements 601-1 to 601-n, which is the width (length) of the light receiving position continuous from the light receiving element 601-n of the array 601 of the laser sensor unit 60b, is calculated as the substrate distance DB (that is, a substrate distance DB1).

(Case of Substrate Cooling Position)

In a case where the substrate 22 is at the substrate cooling position, as illustrated in FIG. 8, the laser beams emitted from the laser emission units 50a and 50b are blocked by the substrates 22a and 22b in a partial distribution range thereof, respectively. For this reason, among the light receiving elements of the array 601 of the laser sensor units 60a and 60b, those corresponding to the height positions of the substrates 22a and 22b do not receive a laser beam, respectively. That is, the laser sensor units 60a and 60b acquire the positions of light receiving elements corresponding to height positions between the upper surface and the lower surface of the substrates 22a and 22b as the non-light receiving positions, and acquire the positions of the other light receiving elements that receive a laser beam as the light receiving positions, respectively.

For example, in a case where the positions of the light receiving elements 601-1 to 601-m in the array 601 of the laser sensor unit 60a are acquired as the light receiving positions, and the positions of the subsequent light receiving elements 601-(m+1) to 601-(m+100) are acquired as the non-light receiving positions, the first distance calculation controller 70a calculates, as the substrate distance DA (that is, a substrate distance DA2), the width (length) of the array of the light receiving elements 601-1 to 601-m, which is the width (length) of the light receiving position continuous from the light receiving element 601-1 as a reference point.

Similarly, for example, in a case where the positions of the light receiving elements 601-(m′) to 601-n in the array 601 of the laser sensor unit 60b are acquired as the light receiving positions, and the positions of the subsequent light receiving elements 601-(m′−1) to 601-(m−100) are acquired as the non-light receiving positions, the second distance calculation controller 70b calculates, as the substrate distance DB (that is, a substrate distance DB2), the width (length) of the array of the light receiving elements 601-(m′) to 601-n, which is the width (length) of the light receiving position continuous from the light receiving element 601-n as a reference point.

For a section between the substrate loading/unloading position and the substrate cooling position, the substrate distances DA and DB are calculated by the first distance calculation controller 70a and the second distance calculation controller 70b in a similar procedure to the substrate cooling position, respectively.

The substrate cooling unit 18 includes the cooling plates 102a and 102b, the substrate holders 103a and 103b, the support shafts 104a and 104b, and the drivers 105a and 105b. In addition, the substrate cooling unit 18 may further include the laser emission units 50a and 50b, the laser sensor units 60a and 60b, the first distance calculation controller 70a, and the second distance calculation controller 70b.

(Controller)

As illustrated in FIG. 9, the controller 121 is configured as a computer including a central processing unit (CPU) 121a, a random access memory (RAM) 121b, a memory device 121c, and an I/O port 121d. The RAM 121b, the memory device 121c, and the I/O port 121d are configured to be able to exchange data with the CPU 121a via an internal bus 121e. An input/output device 122 configured as, for example, a touch panel is connected to the controller 121.

The memory device 121c is configured by, for example, a flash memory or a hard disk drive (HDD). In the memory device 121c, a control program that controls an operation of the substrate processing apparatus, a process recipe in which procedures, conditions, and the like of substrate processing described later are described, and the like are readably stored. The process recipe is combined so as to cause the controller 121 to execute procedures in a substrate processing step described later to obtain a predetermined result, and functions as a program. Hereinafter, the process recipe, the control program, and the like are also collectively and simply referred to as a program. In addition, the process recipe is also simply referred to as a recipe. In the present specification, the term “program” may include only the recipe alone, only the control program alone, or both. The RAM 121b is configured as a memory area (work area) in which programs, data, and the like read by the CPU 121a are temporarily stored.

The I/O port 121d is connected to the atmospheric robot 21, the vacuum robot 36, the L/L drive device 25, the robot arm 17, the drivers 105a and 105b, the refrigerant supply units 109a and 109b, the first distance calculation controller 70a, the second distance calculation controller 70b, the gate valve, the vacuum pump, the heater, and the like.

The CPU 121a is configured to read the control program from the memory device 121c and executes the control program, and to read the recipe from the memory device 121c in response to an input or the like of an operation command from the input/output device 122. The CPU 121a is configured to control a substrate transfer operation by the atmospheric robot 21, a substrate transfer operation by the vacuum robot 36, a substrate support body 24 raising/lowering and rotating operation by the drive device 25, a substrate transfer operation by the robot arm 17, adjustment of a refrigerant temperature and a refrigerant flow rate in the refrigerant supply units 109a and 109b, a substrate raising/lowering operation by the drivers 105a and 105b, a substrate distance DA/DB calculating operation by the first distance calculation controller 70a and the second distance calculation controller 70b, a gate valve opening/closing operation, activation/stop of a vacuum pump, a heater temperature adjusting operation, and the like in accordance with the contents of the read recipe.

The controller 121 can be configured by installing the above-described program stored in an external memory device (for example, a magnetic disk such as a hard disk, an optical disk such as a CD, a magneto-optical disk such as an MO, or a semiconductor memory such as a USB memory) 123 in a computer. The memory device 121c and the external memory device 123 are configured as computer-readable recording media. Hereinafter, these are collectively and simply referred to as a recording medium. In the present specification, the term “recording medium” may include only the memory device 121c alone, only the external memory device 123 alone, or both. Note that the program may be provided to the computer by using a communication means such as the Internet or a dedicated line without using the external memory device 123.

(Substrate Distances DA and DB)

Hereinafter, the substrate distance DA (substrate distance DA1) and the substrate distance DB (substrate distance DB1) at the substrate loading/unloading position, and the substrate distance DA (substrate distance DA2) and the substrate distance DB (substrate distance DB2) at the substrate cooling position will be described in detail.

(Substrate Distances DA1 and DB1)

The substrate distances DA1 and DB1 are appropriately determined according to the positions of the cooling plates 102a and 102b, an interval between the fingers 38a and 38b, and the like, and are predetermined distances in a range of 10 to 200 mm, for example.

(Substrate Distances DA2 and DB2)

The substrate distances DA2 and DB2 are mainly set according to desired cooling characteristics for the substrate 22 in substrate cooling. For example, the substrate distances DA2 and DB2 are predetermined distances in a range of 1 to 20 mm, preferably in a range of 1 to 5 mm. Here, the “cooling characteristics” mainly include a characteristic related to a temperature change of the substrate 22 with respect to cooling time, and particularly includes a change characteristic of an average temperature of the entire in-plane surface of the substrate 22, a change characteristic of a temperature deviation in the in-plane surface of the substrate 22, and the like.

The cooling characteristics for the substrate 22 largely depend on the sizes of the substrate distances DA2 and DB2 during substrate cooling. Therefore, in order to cool the substrates 22 with desired cooling characteristics, it is needed to accurately grasp the substrate distances DA2 and DB2 and to set operation amounts of the drivers 105a and 105b such that the distances are desired values.

In addition, as a cooling rate of the substrate 22 increases, generally, a temperature deviation in the in-plane surface of the substrate 22 tends to increase, and as the temperature deviation increases, a warpage amount of the substrate 22 may increase. Therefore, it is needed to select the substrate distances DA2 and DB2 such that the warpage amount or the in-plane temperature deviation of the substrate 22 does not exceed a predetermined value, and to set operation amounts of the drivers 105a and 105b accurately so as to obtain the selected distances from a viewpoint of suppressing an increase in the warpage amount of the substrate 22.

In addition, as the substrate distances DA2 and DB2 are smaller, the substrate 22 is cooled more rapidly. Therefore, the substrate distances DA2 and DB2 are desirably as small as possible from a viewpoint of improving throughput of cooling. However, in a case where the warpage amount of the substrate 22 increases during cooling, if the sizes of the substrate distances DA2 and DB2 are too small, the substrate 22 may come into contact with the cooling plates 102a and 102b. Therefore, in order to avoid occurrence of such contact, it is desirable to select a value with a certain margin for each of the substrate distances DA2 and DB2 considering a case where warpage of the substrate 22 is generated.

In order to solve such a problem, the substrate cooling unit 18 in the present embodiment is configured to be able to measure the substrate distances DA2 and DB2 during execution of substrate cooling. Here, particularly in a case where warpage is generated in the substrate 22, the distance to each of the cooling plates 102a and 102b varies depending on the in-plane position of the substrate 22. However, according to the present embodiment, as illustrated in FIG. 10, even in a case where warpage is generated in the substrate 22, the shortest distance between the upper surface of the substrate 22a and the lower surface of the cooling plate 102a can be calculated and measured. The same applies to a distance between the lower surface of the substrate 22b and the upper surface of the cooling plate 102b. Since the shortest distance can be reliably measured, it is particularly easy to grasp a possibility of contact between the substrate 22 and the cooling plates 102a and 102b and to set a margin for preventing contact.

Furthermore, in order to solve such a problem, the substrate cooling unit 18 in the present embodiment is configured to be able to measure the amount of warpage of the substrate 22 that is generated during execution of substrate cooling. Then, the substrate distances DA2 and DB2 are selected such that the warpage amount or the in-plane temperature deviation of the substrate 22 does not exceed a predetermined value based on the measured warpage amount, and operation amounts of the drivers 105a and 105b are set so as to obtain the selected distances.

(2) Operation of Substrate Processing Apparatus

Next, a substrate processing flow in the substrate processing apparatus 10 illustrated in FIG. 1 will be described for an operation of the substrate processing apparatus 10 according to the present embodiment.

(Atmosphere Side Loading Step S100)

First, the unprocessed substrates 22 are transferred from the atmospheric transfer chamber 20 into the load lock chamber 14a, and the inside of the load lock chamber 14a is airtightly closed. Thereafter, the gate valve is opened to allow the load lock chamber 14a and the transfer chamber 12 to communicate with each other.

(First Transfer Step S110)

Subsequently, the vacuum robot 36 drives the arm 42 to receive the substrates 22 in the load lock chamber 14a onto the pair of fingers 40. Thereafter, the substrates 22 are loaded into the processing chamber 16a.

The vacuum robot 36 inserts the pair of fingers 40 into the processing chamber 16a and mounts the substrate 22a on the substrate holding table 44a. Furthermore, the vacuum robot 36 transfers the substrate 22b between the robot arm 17 and the pair of fingers 40. The robot arm 17 operates so as to mount the received substrate 22b on the substrate holding table 44b.

(Substrate Processing Step S120)

Thereafter, the substrates 22 on the substrate holding tables 44a and 44b are heated by a heater and subjected to predetermined processing.

(Second Transfer Step S130)

When the processing in the processing chamber 16a is completed, the vacuum robot 36 inserts the pair of fingers 40 into the processing chamber 116a, receives the substrate 22a from the substrate holding table 44a, and receives the substrate 22b from the robot arm 17. Subsequently, the vacuum robot 36 transfers and loads the substrates 22 from the inside of the processing chamber 16a into the substrate cooling unit 18.

(Substrate Cooling Step S140)

The substrates 22 transferred to the substrate cooling unit 18 are cooled in the substrate cooling unit 18 until the temperature of the substrates 22 reaches a predetermined temperature.

Details of the second transfer step S130 and the substrate cooling step S140 will be described later as step A.

(Third Transfer Step S150)

When the substrates 22 are cooled until the temperature of the substrates 22 reaches a predetermined temperature, the vacuum robot 36 inserts the pair of fingers 40 into the substrate cooling unit 18 to receive the substrates 22 on the pair of fingers 40, and then transfers the substrates 22 into the load lock chamber 14b.

(Atmosphere side Unloading Step S160)

The gate valve on the transfer chamber 12 side is closed, and then the inside of the load lock chamber 14b is opened to the atmosphere. Thereafter, the substrates 22 are transferred from the inside of the load lock chamber 14b to the atmospheric transfer chamber 20, and are unloaded to the outside by an external transfer device (not illustrated).

(2-1) A Series of Steps of Cooling Substrate in Substrate Cooling Unit (Step A)

Subsequently, an operation of controlling the vacuum robot 36 and the drivers 105a and 105b to transfer and cool the substrate 22 in a series of steps of cooling the substrate 22 in the substrate cooling unit 18 will be described in detail below.

(Substrate Loading Step SA10)

A step of loading the substrates 22 into the substrate cooling unit 18 and holding the substrates 22 on the substrate holders 103a and 103b is performed by the following steps (SA100 to SA130).

(Finger Mounting Step SA100)

The two substrates the temperature of which has been raised and which have been heated (for example, annealed or subjected to film forming processing) in the processing chambers 16a and 16b are mounted so as to be supported on the upper finger 38a and the lower finger 38b via the robot arm 17, respectively. In the present embodiment, the temperature of the substrates 22 is raised to about 400° C. at the time of the step.

(Finger Insertion Step SA110)

In a state where the substrates 22a and 22b are supported on the upper finger 38a and the lower finger 38b, respectively, the vacuum robot 36 inserts the pair of fingers 40 into the cooling chamber 101 such that the upper finger 38a is positioned above the substrate holder 103a and the lower finger 38b is positioned above the substrate holder 103b. At this time, the substrate holders 103a and 103b are raised and lowered to the substrate loading/unloading positions by the drivers 105a and 105b, respectively. In the present embodiment, the temperature of the substrates 22 is about 300° C. at the time of the step.

(Finger Lowering Step SA120)

Subsequently, the vacuum robot 36 lowers the pair of fingers 40 to hold the substrates 22a and 22b on the substrate holders 103a and 103b, respectively. Note that in order to hold the substrates 22a and 22b on the substrate holders 103a and 103b, the substrate holders 103a and 103b may be raised and lowered, respectively.

(Finger Retraction Step SA130)

Subsequently, the vacuum robot 36 moves the pair of fingers 40 so as to retract the upper finger 38a from below the substrate holder 103a and to retract the lower finger 38b from below the substrate holder 103b to the outside of the cooling chamber 101.

In the substrate loading step SA10, after the substrates 22a and 22b are held, the first distance calculation controller 70a and the second distance calculation controller 70b control the laser emission units 50a and 50b to start laser emission, and start processing of calculating the substrate distances DA and DB (that is, distance measurement processing) based on at least one of the light receiving position and the non-light receiving position acquired from the laser sensor units 60a and 60b, respectively.

In the present embodiment, laser emission is continued until a substrate unloading step S50 described later, and distance measurement processing is continuously executed at a predetermined cycle. The predetermined cycle can be arbitrarily set according to a purpose of distance measurement or the like, and is, for example, in a range of 10 millisecond (ms) to 5 seconds.

However, as another embodiment, in conjunction with control of controlling the drivers 105a and 105b to raise and lower the substrate holders 103a and 103b, the distance measurement processing may be executed only in a state where the substrate 22 is at the substrate loading/unloading position and a state where the substrate 22 is at the substrate cooling position. In addition, the distance measurement processing may be executed only in a state where the substrate 22 is at the substrate cooling position.

(Substrate Raising/Lowering Step SA20)

Subsequently, the driver 105a raises the substrate holder 103a and the substrate 22a to the substrate cooling position. Similarly, the driver 105b lowers the substrate holder 103b and the substrate 22b to the substrate cooling position. Here, each of the drivers 105a and 105b performs the raising/lowering operation based on an operation amount instructed by the controller 121.

(Substrate Cooling Step SA30)

Subsequently, the substrates 22a and 22b are cooled by the cooling plates 102a and 102b close to the substrates 22a and 22b, respectively, while a state in which the substrate holders 103a and 103b are stopped at the substrate cooling position for a predetermined time is maintained. In the present embodiment, cooling in this step is performed for 60 seconds, and the substrate 22 is cooled until the temperature of the substrate 22 reaches about 100 to 150° C. Note that in the cooling plates 102a and 102b, the refrigerant is supplied in advance from the refrigerant supply units 109a and 109b into the refrigerant flow paths 106a and 106b, respectively, and surfaces of the cooling plates 102a and 102b facing the substrate 22 are cooled until the temperature of the surfaces reaches a predetermined temperature. For example, the predetermined temperature is about −10 to 50° C. In a step B described later, an adjustment step is performed particularly based on the substrate distances DA2 and DB2 measured during execution of this step. In addition, steps C and D described later each include a step of measuring the substrate distances DA2 and DB2 during execution of this step.

(Substrate Raising/Lowering Step SA40)

Subsequently, the driver 105a lowers the substrate holder 103a and the substrate 22a to the substrate loading/unloading position. Similarly, the driver 105b lowers the substrate holder 103b and the substrate 22b to the substrate loading/unloading position.

(Substrate Unloading Step SA50)

After the substrates 22 are raised or lowered to the substrate loading/unloading position, the substrates 22 are again supported on the upper finger 38a and the lower finger 38b by the vacuum robot 36, respectively, and are unloaded from the inside of the cooling chamber 101. This step is performed by executing the above-described substrate loading step SA10 in the reverse order.

(2-2) Driver Amendment Step Based on Substrate Distance Measurement (step B)

Subsequently, a step of adjusting the operation amounts of the drivers 105a and 105b based on the substrate distances DA and DB measured in the above-described series of steps of cooling the substrate (step A) will be described. Note that the step B and the step A performed before adjustment is performed in the step B are each performed as one step of adjusting the substrate cooling unit 18.

The drivers 105a and 105b each configured by an air cylinder or the like operate based on an operation amount instructed by the controller 121. Here, it is desirable to set the substrate distances DA2 and DB2 to distances a and b, respectively. However, actually, the substrate distances DA2 and DB2 may be different values (distance a′ and b′), respectively, due to a factor such as a mechanical operation error of the drivers 105a and 105b. Therefore, in the present embodiment, the substrate distances DA2 and DB2 (distance a′ and b′) measured in the substrate cooling step SA30 of the above-described step A are compared with the desired distances a and b, respectively, and the operation amount of the driver is adjusted by a difference thereof (a-DA2 or b-DB2). Note that the substrate distances DA2 and DB2 may fluctuate due to warpage generated in the substrate 22 during cooling, and therefore this difference is desirably calculated particularly by setting the substrate distances DA2 and DB2 measured at the time when the substrate cooling step SA30 is started to the distances a′ and b′, respectively.

Specifically, the operation amount instructed to the drivers 105a and 105b by the controller 121 is amended by this difference. In addition, a regulator (for example, a regulating plate) that regulates the operation width of each of the drivers 105a and 105b within a predetermined range may be disposed, and the regulator may be adjusted (for example, the position of the regulating plate may be adjusted) such that the substrate distances DA2 and DB2 are amended by this difference.

As described above, in the present embodiment, based on the substrate distances DA2 and DB2 measured in the step A, the operation amounts of the drivers 105a and 105b (or the substrate holding mechanism) can be adjusted such that the values of DA2 and DB2 are desired values, and therefore the substrate 22 can be easily cooled with desired cooling characteristics.

Note that in the present embodiment, the orientations of surfaces of the substrate 22a and the substrate 22b cooled by the cooling plates 102a and 102b are different between the front and the back, respectively. Therefore, the substrate distances DA2 and DB2 during cooling are also desirably set so as to be different from each other depending on the film type, structure, and the like formed on the surfaces of the substrates 22a and 22b, respectively. Therefore, as in the present embodiment, the substrate distances DA2 and DB2 are preferably configured to be individually measurable.

(2-3) Substrate Warpage Amount Monitoring Step Based on Substrate Distance Measurement (Step C)

Subsequently, a step of detecting warpage generated in the substrate 22 during cooling and measuring a warpage amount based on the substrate distances DA and DB measured in the above-described series of steps of cooling the substrate (step A) will be described. Note that the step C can be performed as one step in the step A. In addition, the step C can be performed as one step of adjusting the substrate cooling unit 18, or can be performed as one of steps of processing a substrate for a product.

In the step C, generation of warpage in the substrate 22 is detected and a warpage amount is measured by continuously repeating measurement (calculation) of the substrate distances DA2 and DB2 during the substrate cooling step SA30 in the step A.

Specifically, first, the substrate distances DA2 and DB2 are measured at the start time of the substrate cooling step SA30 for starting substrate cooling, that is, at the time when the substrate 22 is raised or lowered to the substrate cooling position. Here, the substrate distances DA2 and DB2 at this time point are particularly referred to as DA2 (T0) and DB2 (T0), respectively.

Subsequently, while substrate cooling is executed, that is, while the substrate 22 is maintained at the substrate cooling position, the substrate distances DA2 and DB2 are continuously and repeatedly measured. Here, after the measurement is started, the number of times of execution of the measurement is counted from 1 to k (k is a natural number), and the substrate distances DA2 and DB2 measured at the k-th time are particularly referred to as DA2 (Tk) and DB2 (Tk), respectively.

Then, the controller 121 calculates a difference value between DA2 (T0) and DA2 (Tk) as a warpage amount of the substrate 22a generated during cooling. Similarly, the controller 121 calculates a difference value between DB2 (T0) and DB2 (Tk) as a warpage amount of the substrate 22b generated during cooling. In particular, as illustrated in FIG. 10, in a case where warpage in which the substrate 22 is deformed into a protrusion shape is generated, a change in the height position of a central portion of the substrate 22 is calculated as a warpage amount generated during cooling. In addition, in a case where warpage in which the substrate 22 is deformed into a recess shape is generated, a change in the height position of an outer edge portion of the substrate 22 is calculated as a warpage amount generated during cooling.

DA2 The controller 121 may be configured to determine that warpage is generated in the substrate 22 in a case where a difference value between DA2 (T0) and DA2 (Tk) (or a difference value between DB2 (T0) and DB2 (Tk)) exceeds a predetermined first threshold.

Furthermore, the controller 121 may be configured to control the drivers 105a and 105b in a case where the difference value exceeds a predetermined second threshold such that the substrate 22 moves away from the cooling plates 102a and 102b. As a result, the warpage generated in the substrate 22 can be prevented from exceeding a predetermined amount. Note that, in the present embodiment, since the orientations of surfaces of the substrate 22a and the substrate 22b cooled by the cooling plates 102a and 102b are different between the front and back, respectively, the second threshold for the substrate 22a and the second threshold for the substrate 22b may be different from each other.

(2-4) Substrate Contact Avoidance Step Based on Substrate Distance Measurement (Step D)

Subsequently, a step of avoiding the substrate 22 from coming into contact with the cooling plates 102a and 102b due to warpage generated in the substrate 22 during cooling based on the substrate distances DA and DB measured in the above-described series of steps of cooling the substrate (step A) will be described. Note that the step D can be performed as one step in the step A.

In the step D, by continuously repeating the measurement (calculation) of the substrate distances DA2 and DB2 during the substrate cooling step SA30 in the step A, in a case where it is detected that the warped substrate 22 approaches the cooling plates 102a and 102b by a distance shorter than a predetermined distance, the drivers 105a and 105b are controlled to move the substrate 22 away before the substrate 22 comes into contact with the cooling plates 102a and 102b.

Specifically, in the step D, similarly to the step C, DA2 (Tk) is continuously measured (calculated) during the substrate cooling step SA30 in the step A. The controller 121 is configured to control the driver 105a to lower the substrate 22a such that the substrate 22a moves away from the cooling plate 102a in a case where DA2 (Tk) is smaller than a predetermined threshold. Similarly, the controller 121 is configured to control the driver 105b to raise the substrate 22b such that the substrate 22b moves away from the cooling plate 102b in a case where DB2 (Tk) is smaller than a predetermined threshold.

The technology of the present disclosure makes it possible to perform cooling so as to approach desired cooling characteristics in cooling a substrate.

The entire disclosure of Japanese Patent Application No. 2019-167921 filed on Sep. 17, 2019 is incorporated herein by reference.

All documents, patent applications, and technical standards described in the present specification are incorporated herein by reference to the same extent as a case where each of the individual documents, the patent applications, and the technical standards is specifically and individually described to be incorporated by reference.

What is claimed is:

1. A substrate cooling unit comprising:
a substrate holding mechanism that holds a substrate horizontally;
a driver that raises and lowers the substrate holding mechanism;
a cooling plate having a surface facing a surface of the substrate held by the substrate holding mechanism;
a laser emitter that is disposed at one lateral end of a space in which the substrate held by the substrate holding mechanism is raised and lowered and that emits a laser beam distributed with a width in a direction in which the substrate holding mechanism is raised and lowered and parallel to the surface of the substrate held by the substrate holding mechanism;
a laser receiver that is disposed at the other lateral end of the space and that acquires light receiving position specifying information indicating a position at which the laser beam emitted from the laser emitter is received in the direction in which the substrate holding mechanism is raised and lowered; and
a calculator configured to be capable of calculating a distance between the facing surface of the cooling plate and the facing surface of the substrate held by the substrate holding mechanism to the cooling plate based on the light receiving position specifying information acquired by the laser receiver.

2. The substrate cooling unit according to claim 1, wherein the laser emitter is configured to emit a laser beam having a predetermined width in a direction in which the substrate holding mechanism is raised and lowered.

3. The substrate cooling unit according to claim 1, wherein the laser emitter includes a plurality of laser oscillators arrayed at predetermined intervals in a direction in which the substrate holding mechanism is raised and lowered.

4. The substrate cooling unit according to claim 1, wherein the laser emitter is configured to emit the laser beam such that a height position of the facing surface of the cooling plate is included in the laser distribution.

5. The substrate cooling unit according to claim 4, wherein the laser emitter is configured to emit the laser beam such that a range in a height direction in which the substrate held by the substrate holding mechanism is raised and lowered is included in the laser distribution.

6. The substrate cooling unit according to claim 4, wherein
the laser receiver acquires information of a light receiving position of the laser beam as the light receiving position specifying information, and
the calculator calculates, as the distance, a width of the light receiving position continuous from the height position of the facing surface of the cooling plate based on the information of the light receiving position acquired by the laser receiver.

7. The substrate cooling unit according to claim 4, wherein
the laser receiver acquires information of a non-light receiving position of the laser beam as the light receiving position specifying information, and
the calculator calculates, as the distance, a distance from the height position of the facing surface of the cooling plate to the non-light receiving position based on the information of the non- light receiving position acquired by the laser receiver.

8. The substrate cooling unit according to claim 1, wherein the laser emitter and the laser receiver are disposed outside a cooling chamber in which the substrate holding mechanism is disposed, and emit and receive the laser beam through windows disposed at one lateral end and the other lateral end of the cooling chamber, respectively.

9. The substrate cooling unit according to claim 1, further comprising:
a controller configured to control the driver to raise and lower the substrate holding mechanism to a predetermined position so as to bring the substrate held by the substrate holding mechanism close to the cooling plate, to control the driver to cool the substrate by maintaining a state in which raising and lowering of the substrate holding mechanism is stopped for a predetermined time after the raising and lowering, and to cause the calculator to calculate the distance at least when the cooling is performed.

10. The substrate cooling unit according to claim 9, wherein the controller is configured to cause the calculator to calculate the distance continuously and repeatedly at least when the cooling is performed.

11. The substrate cooling unit according to claim 10, wherein the controller is configured to be capable of calculating a difference value between the distance calculated when the cooling starts and the distance continuously calculated during the cooling as a warpage amount of the substrate generated during the cooling.

12. The substrate cooling unit according to claim 10, wherein the controller is configured to be capable of controlling the driver to move the substrate held by the substrate holding mechanism away from the cooling plate in a case where the distance calculated by the calculator is smaller than a predetermined threshold.

13. The substrate cooling unit according to claim 11, wherein the controller is configured to be capable of controlling the driver to move the substrate held by the substrate holding mechanism away from the cooling plate in a case where the calculated difference value exceeds a predetermined threshold.

14. A substrate processing apparatus comprising:
the substrate cooling unit according to claim 1;
a processing chamber that heats the substrate; and
a substrate transfer device that transfers the substrate processed in the processing chamber to the substrate cooling unit.

15. The substrate processing apparatus according to claim 14, further comprising:
a controller configured to be capable of controlling the driver to raise and lower the substrate holding mechanism to a predetermined position so as to bring the substrate held by the substrate holding mechanism close to the cooling plate, and controls the driver to cool the substrate by maintaining a state in which the substrate holding mechanism is stopped for a predetermined time after the raising and lowering, wherein
the controller is configured to control the calculator to calculate the distance at least when the cooling is performed.

16. A substrate processing method, the method comprising:
causing a substrate holding mechanism that holds a substrate horizontally to hold the substrate;
raising and lowering the substrate holding mechanism to a predetermined position so as to bring the substrate held by the substrate holding mechanism close to a cooling plate having a surface facing a surface of the substrate;
cooling the substrate by maintaining a state in which the substrate holding mechanism is stopped for a predetermined time after the substrate holding mechanism is raised and lowered;
emitting a laser beam distributed with a width in a direction in which the substrate holding mechanism is raised and lowered and parallel to the surface of the substrate held by the substrate holding mechanism from one lateral end of a space in which the substrate held by the substrate holding mechanism is raised and lowered to the other lateral end, receiving the laser beam at the other lateral end, and acquiring light receiving position specifying information indicating a position where the laser beam is received in the direction in which the substrate holding mechanism is raised and lowered; and
calculating a distance between the facing surface of the cooling plate and the facing surface of the substrate held by the substrate holding mechanism to the cooling plate based on the light receiving position specifying information.

17. A method for manufacturing a semiconductor substrate, comprising:
preparing a semiconductor substrate; and
processing the substrate processing method according to claim 16.

18. A non-transitory computer-readable recording medium storing a program that causes, by a computer, a substrate processing apparatus to perform a process comprising:
causing a substrate holding mechanism of a substrate cooling unit included in the substrate processing apparatus to hold a substrate horizontally;
raising and lowering the substrate holding mechanism to a predetermined position so as to bring the substrate held by the substrate holding mechanism close to a cooling plate having a surface facing a surface of the substrate;
cooling the substrate by maintaining a state in which the substrate holding mechanism is stopped for a predetermined time after the substrate holding mechanism is raised and lowered;
emitting a laser beam distributed with a width in a direction in which the substrate holding mechanism is raised and lowered and parallel to the surface of the substrate held by the substrate holding mechanism from one lateral end of a space in which the substrate held by the substrate holding mechanism is raised and lowered to the other lateral end, receiving the laser beam at the other lateral end, and acquiring light receiving position specifying information indicating a position where the laser beam is received in the direction in which the substrate holding mechanism is raised and lowered; and
calculating a distance between the facing surface of the cooling plate and the facing surface of the substrate held by the substrate holding mechanism to the cooling plate based on the light receiving position specifying information.
